(19) United States
(12) Patent Application Publication
(10) Pub. No.: US 2015/0280412 A1
(43) Pub. Date: Oct. 1, 2015

(54) ELECTRONIC DEVICE MOUNTING APPARATUS

(71) Applicant: FUJITSU LIMITED, Kawasaki-shi (JP)

(72) Inventor: Yosuke Tanaka, Kamakura (JP)

(73) Assignee: FUJITSU LIMITED, Kawasaki-shi (JP)

(21) Appl. No.: 14/541,192

(22) Filed: Nov. 14, 2014

(30) Foreign Application Priority Data
Mar. 31, 2014 (JP) 2014-071605

(51) Int. Cl. H02G 3/32; H05K 9/00; H05K 7/14

(52) U.S. Cl. CPC H02G 3/32; H05K 7/14; H05K 9/0062

(57) ABSTRACT

An electronic device mounting apparatus includes: a rack configured to be slidably loaded with an electronic device; and a cable management arm configured to support a cable of the electronic device, wherein the cable management arm includes: a first arm member including a first base end which is fixed to be rotatable with respect to the electronic device around a first rotation shaft extending in a vertical direction; and a second arm member including a second base end which is fixed to be rotatable with respect to the rack around a second rotation shaft extending in the vertical direction.

### CROSS-REFERENCE TO RELATED APPLICATION

This application is based upon and claims the benefit of priority from the prior Japanese Patent Application No. 2014-071605 filed on Mar. 31, 2014, the entire contents of which are incorporated herein by reference.

### FIELD

The embodiments discussed herein are related to an electronic device mounting apparatus.

### BACKGROUND

A rack mount type electronic device such as a server or a storage device is slid in relation to a rack for the purpose of, for example, inspection and maintenance. In order to suppress interference between a cable such as a power cable or a data cable of the electronic device and the rack while the electronic device is slid, the cable is supported by a cable management arm including a pair of arm members which are foldable on a plane (a cross section) defined by a width direction and a depth direction of the rack.

A related technology is disclosed in Japanese Laid-Open Patent Publication No. 2003-263242.

### SUMMARY

An electronic device mounting apparatus includes: a rack configured to be slidably loaded with an electronic device; and a cable management arm configured to support a cable of the electronic device, wherein the cable management arm includes: a first arm member including a first base end which is fixed to be rotatable with respect to the electronic device around a first rotation shaft extending in a vertical direction; and a second arm member including a second base end which is fixed to be rotatable with respect to the rack around a second rotation shaft extending in the vertical direction.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 illustrates an exemplary electronic device mounting apparatus;

FIG. 2 illustrates the exemplary electronic device mounting apparatus;

FIG. 3 illustrates an exemplary perspective view of a storage device;

FIG. 4 illustrates an exemplary perspective view of a cable management arm;

FIG. 5 illustrates an exemplary cable management arm;

FIG. 6 illustrates an exemplary space occupied by a cable management arm;

FIG. 7 illustrates an exemplary space occupied by a cable management arm;

FIG. 8 illustrates an exemplary cable management arm;

FIG. 9 illustrates an exemplary twist occurring on a cable;

FIG. 10 illustrates an exemplary measure of reducing a twist of a cable;

FIG. 11 illustrates an exemplary perspective view of a rotating mechanism;

FIG. 12 illustrates an exemplary perspective view of a rotating mechanism;

FIG. 13 illustrates an exemplary plan view of the rotating mechanism of FIG. 12;

FIG. 14 illustrates an exemplary side view of the rotating mechanism of FIG. 12;

FIG. 15 illustrates an exemplary perspective view of a first arm member and a second arm member in a developed state; and

FIG. 16 illustrates an exemplary connection member.

### DESCRIPTION OF EMBODIMENTS

The cable has a tolerable minimum bending radius. Therefore, an angle formed between the pair of arm members may not be reduced in a state where the electronic device is pushed into the rack so that a space in the depth direction which is occupied by the cable management arm may be increased. The size of an electronic device mounted on a rack having a defined size may not be increased, and, for example, the capacity of a storage device that accommodates a plurality of hard discs may not increase.

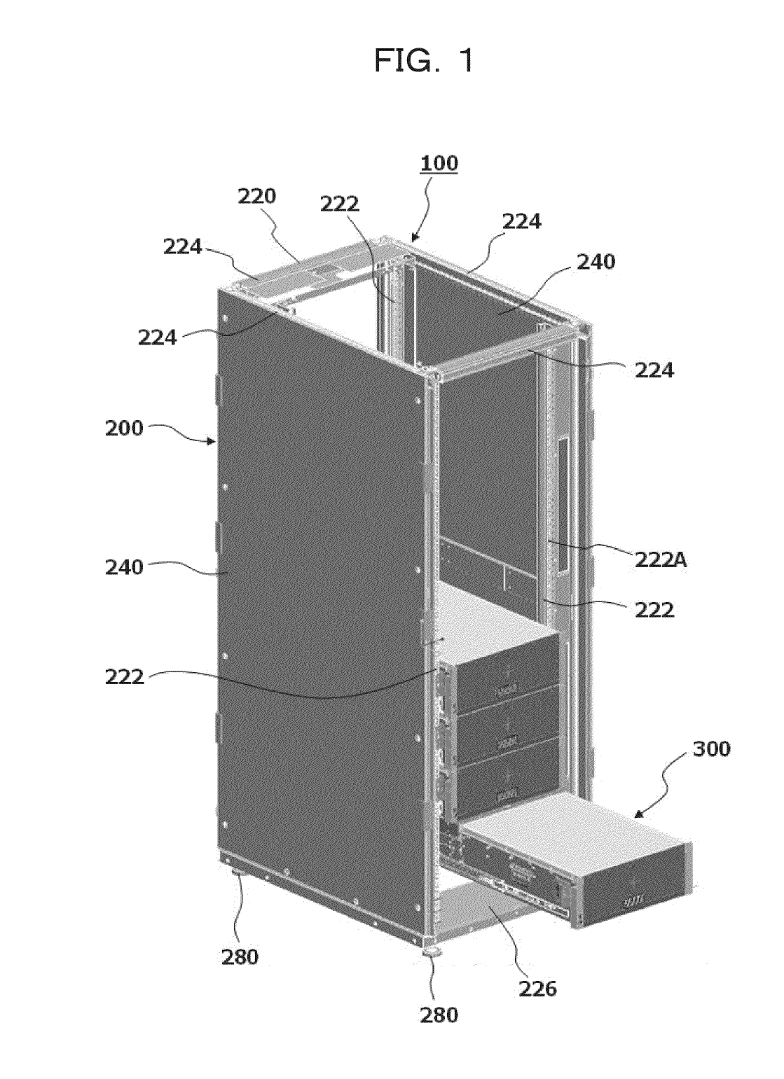

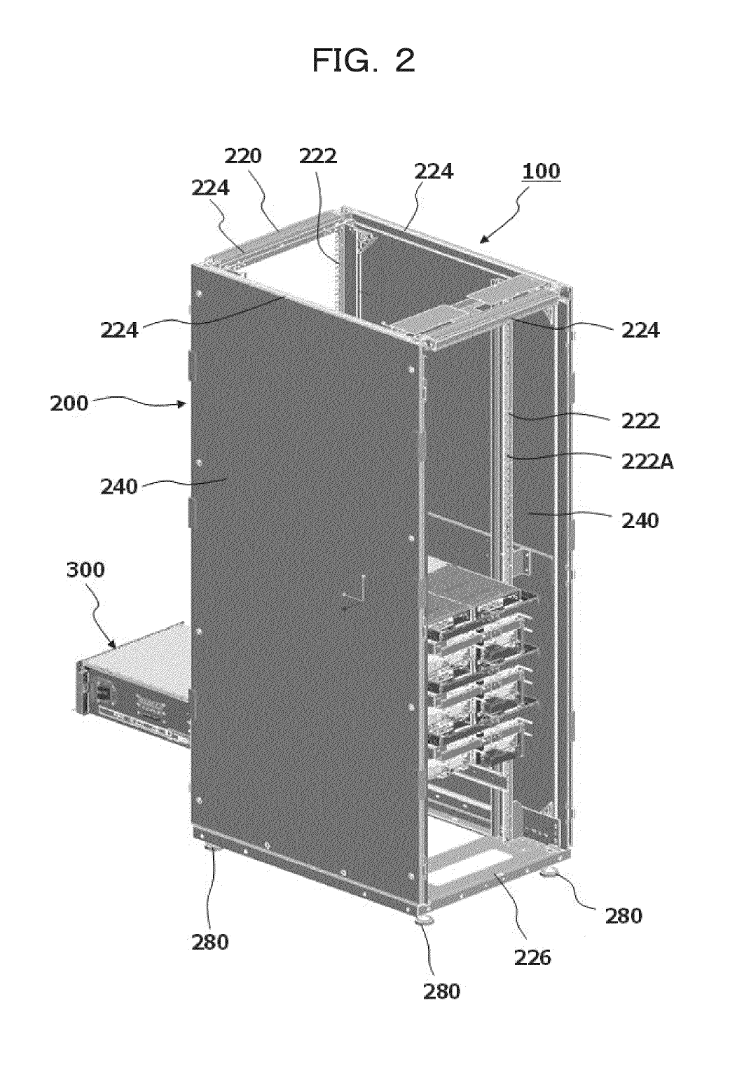

FIGS. 1 and 2 illustrate an exemplary electronic device mounting apparatus. FIG. 1 illustrates a perspective view of the electronic device mounting apparatus 1 which is viewed from an oblique front side. FIG. 2 is a perspective view of the electronic device mounting apparatus from an oblique rear side.

The electronic device mounting apparatus 100 includes a rack 200 and a rack mount type storage device 300 which is mounted to be slidable in relation to the rack 200. For example, the electronic device mounting apparatus 100 is provided with the rack 200 in which the storage device 300 is mounted to be slidable. The storage device 300 may be an exemplary electronic device. The rack mount type electronic device may be, for example, a server, without being limited to the storage device 300.

The rack 200 includes frames 220 which form the sides of a substantially rectangular parallelepiped shape, respectively, and a plate member 240 which has a substantially rectangular shape and covers the outer surfaces in the width direction of the frames 220. The frames 220 include four column members 222 which extend in a vertical direction, four beam members 224 which connect the upper ends of the column member 222 with each other, and a base member 226 fixed to the lower ends of the column members 222. The column members 222 and the beam members 224 may include, for example, an angle member with a substantially L-shaped cross section and a channel member with a substantially U-shaped cross section. The base member 226 has a substantially rectangular shape in a plan view. The base member 226 may be formed with a weight reduction hole for the purpose of, for example, reducing the weight thereof. The column member 222 is formed with a plurality of mounting holes 222A at certain intervals along a material axis direction so that a mounting position of slide rails 260 may be properly changed. Leg members 280 with a height adjustment function are mounted at four corners of the bottom surface of the base member 226, respectively.

The storage device 300 has a substantially rectangular parallelepiped shape, and at least the width thereof is defined as a certain size such as, for example, 19 inches. In the case of the 19 inch width, the height of the storage device 300 is defined, for example, with 1 U (1.75 inches) as a unit, as an integer multiple of the unit (e.g., 4 U).

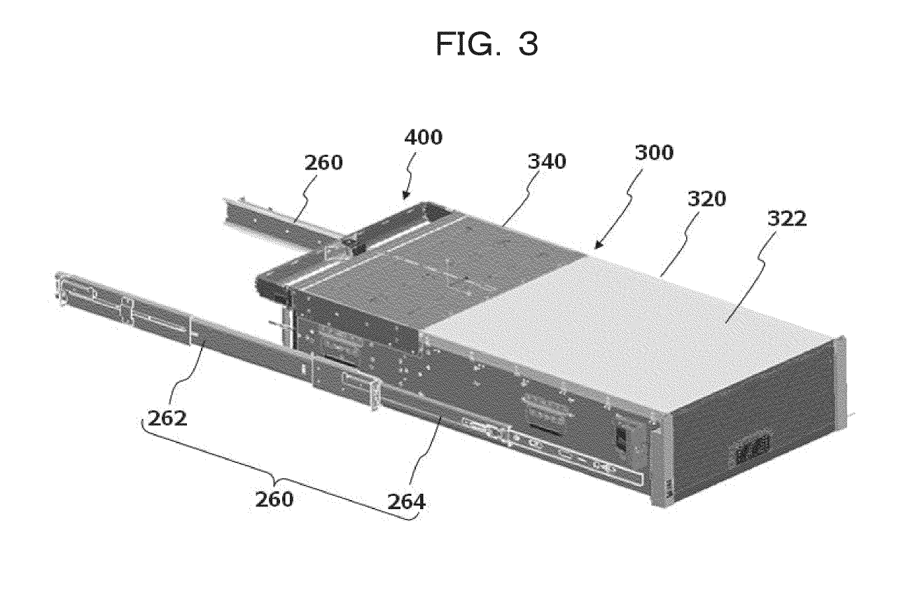

FIG. 3 is an exemplary perspective view of the storage device. As illustrated in FIG. 3, the storage device 300 includes, at a front side protruding from the rack 200, a HDD mounting section 320 in which a hard disc is mounted, and at a rear side facing an inner portion of the rack 200, a unit mounting section 340 in which various units are mounted. In the HDD mounting section 320, for example, a plurality of 3.5 inch hard discs is removably mounted uprightly and vertically and horizontally (in an array). In the unit mounting section 340, for example, a control unit, a power unit, and a fan unit are mounted. A top plate 322 is removably attached to the top surface of the HDD mounting section 320.

The storage device 300 is mounted to be capable of being pulled out (slid) forward on a cross section of the rack 200 through the slide rails 260, each of which is fixed to two column members 222 positioned at one of both sides of the rack 200 which are provided with the two column members 222. The slide rails 260 include outer rails 262 fixed to the mounting holes 222A of the column members 222 through fasteners, and inner rails 264 coupled to be relatively movable in the material axis directions within the outer rails 262. Both lateral sides of the storage device 300 are fixed to the inner surfaces of the inner rails 264 through fasteners. Accordingly, when a force of pulling out the storage device 300 from the rack 200 is applied, the inner rails 264 are relatively displaced in relation to the outer rails 262 in the material axis direction, and pulled out to the position where the storage device 300 integrated with the inner rails 264 protrudes from the rack 200.

In this manner, four storage devices 300 are mounted in the rack 200 in a state where the storage devices 300 are stacked with each other in the vertical direction (in an up-and-down direction) so as to construct the electronic device mounting apparatus 100. The number of storage devices 300 mounted in the rack 200 may be four. However, any other number of storage devices 300 may be mounted.

On the rear surface of each storage device 300, for example, a cable such as a power cable which is supplied with power from an external commercial power supply, or a data cable which transmits/receives various data between an external device and the storage device 300 is mounted. Considering that the storage device 300 is pulled out from the rack 200 when, for example, inspection and maintenance of the storage device 300 are performed, an extra length is secured in the cable so as to allow the storage device 300 to be pulled out from the storage rack 200. The cable may be removably connected to the storage device 300 through a connector to be replaceable due to, for example, breakage or deterioration thereof.

If the extra length of the cable positioned on the rear surface of the storage device 300 interferes with, for example, the frames 220 of the rack 200 or the other storage devices 300 positioned above and below the storage device 300 when the storage device 300 is pulled out from the rack 200, breakage or deterioration may be caused. Thus, a cable management arm (CMA) 400 is mounted on the rack 200. The CMA exhibits, for example, a function of adjusting the extra length of the cable or preventing the cable from hanging down when the storage device 300 is pulled out.

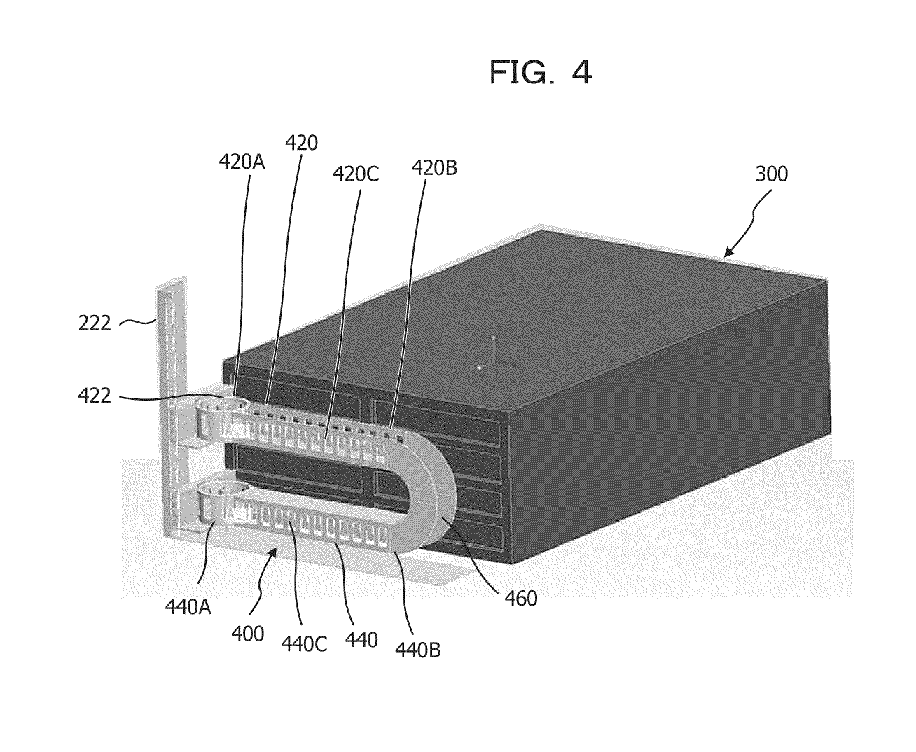

FIG. 4 illustrates an exemplary perspective view of a cable management arm. The CMA 400 is disposed within an internal space of the rack 200 positioned at the rear side of the storage device 300. As illustrated in FIG. 4, the CMA 400 includes a first arm member 420 with a base end 420A fixed to one of the left and right sides of the rear surface of the storage device 300, and a second arm member 440 with a base end 440A attached to one of left and right column members 222 positioned at the rear side of the rack 200. The first arm member 420 and the second arm member 440 are mounted on the left side or right side on the rear surface of the storage device 300 which is common thereto.

The first arm member 420 may include, for example, a linear channel member which has an open at a top surface. The base end 420A of the linear channel member is fixed to be rotatable around a first rotation shaft 422 extending in the vertical direction. The second arm member 440 may include, for example, a linear channel member which has an open at a bottom surface. The base end 440A of the linear channel member is fixed to be rotatable around a second rotation shaft 442 extending in the vertical direction. The first arm member 420 and the second arm member 440 are formed with a plurality of insertion holes 420B and a plurality of insertion holes 440B, respectively, so that, for example, binding bands, which maintain the cable laid along the recesses of the first arm member 420 and the second arm member 440, may be inserted through the insertion holes 420B and 440B to fix the cable. The first arm member 420 and the second arm member 440 may include a channel member, or may include, for example, a pipe material, a rod material, or a sheet material.

A front end 420C of the first arm member 420 and a front end 440C of the second arm member 440 are coupled with each other through a flexible connection member 460 including an elastic material, for example, a film-like material such as a Mylar sheet, a metal material such as a wire net, a leather, a fabric material or the like. Since the front end 420C of the first arm member 420 and the front end 440C of the second arm member 440 are indirectly coupled with each other by the cable, the connection member 460 may not be provided.

The first arm member 420 and the second arm member 440 are disposed to be spaced apart from each other in the vertical direction by a certain distance. The certain distance may be set such that the bottom surface of the recess of the first arm member 420 and the bottom surface of the recess of the second arm member 440 are at least two times the tolerable minimum bending radius of the cable. According to this, the cable laid between the first arm member 420 and the second arm member 440 is bent at least with a tolerable minimum bending radius and, therefore, the cable wiring requirement for a cable may be satisfied.

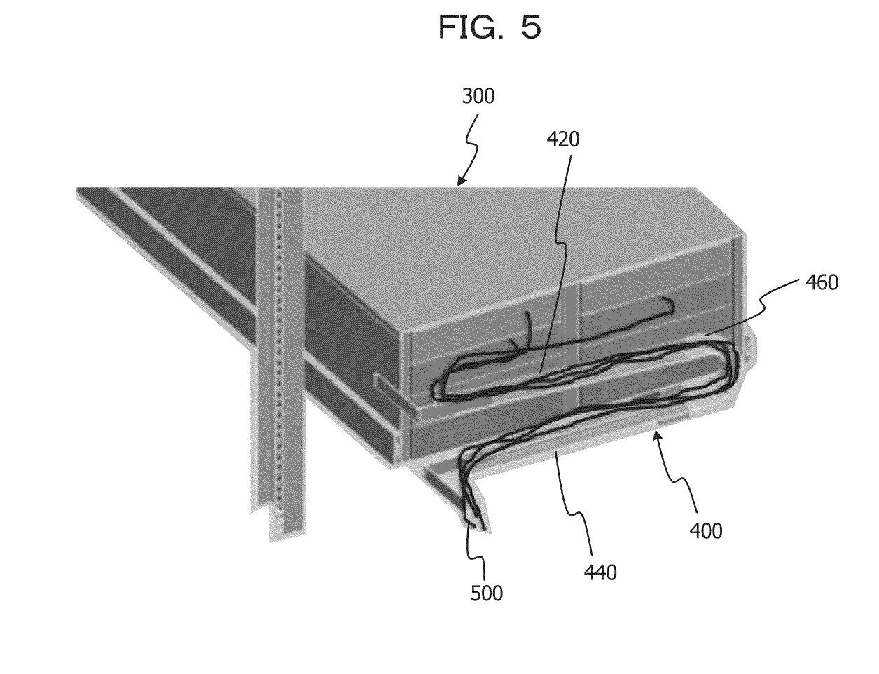

FIG. 5 illustrates an exemplary cable management arm. FIG. 5 is a perspective view illustrating a state of the cable management arm when the storage device 300 is pushed into the rack 200. In the state where the storage device 300 is pushed into the rack 200, the first arm member 420 and the second arm member 440 of the CMA 400 are overlapped with each other when viewed in a plan view, as illustrated in FIG. 5. At this time, since the first arm member 420 and the second arm member 440 are disposed to be spaced apart from each other in the vertical direction by a certain distance, the cable 500 is bent at least with the tolerable minimum bending radius so that the cable wiring condition may be satisfied. Therefore, no problem may occur even after using for a long period. Since the cable 500 is bent in the vertical direction, the space required for installing the CMA 400 in the depth direction of the rack 200 (depth space) is reduced. Therefore, the storage device 300 may be enlarged by that amount.

For example, the height of the storage device 300 may be about 4 U (about 177.8 mm). When the tolerable minimum bending radius of the cable 500 is, for example, 80 mm, the CMA 400 may be disposed within the vertical range of the storage device 300.

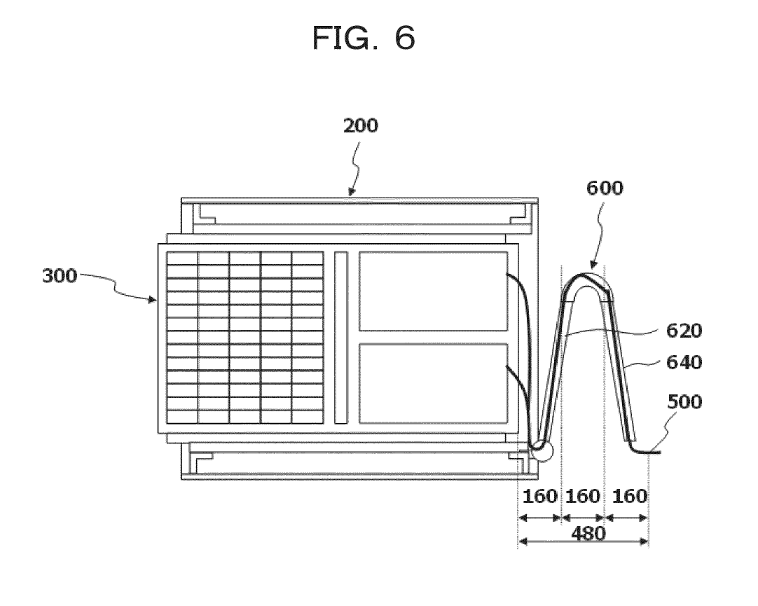

FIG. 6 illustrates an exemplary space occupied by a cable management arm. For example, in a CMA 600, since a first arm member 620 and a second arm member 640 are positioned on a cross section of the rack 200 as illustrated in FIG. 6, a depth space of 160 mm (2×80=160 mm) exists at a bent location of the cable 500. The cable 500 is bent at three locations including a location where the cable 500 is guided from the storage device 300 to the CMA 600, a location where the cable 500 is laid from the first arm member 620 to the second arm member 640 of the CMA 600, and a location where the cable 500 is pulled out from the CMA 600 to the outside. Therefore, a depth space of 480 mm (160×3=480 mm) exists in the CMA 600 illustrated in FIG. 6.

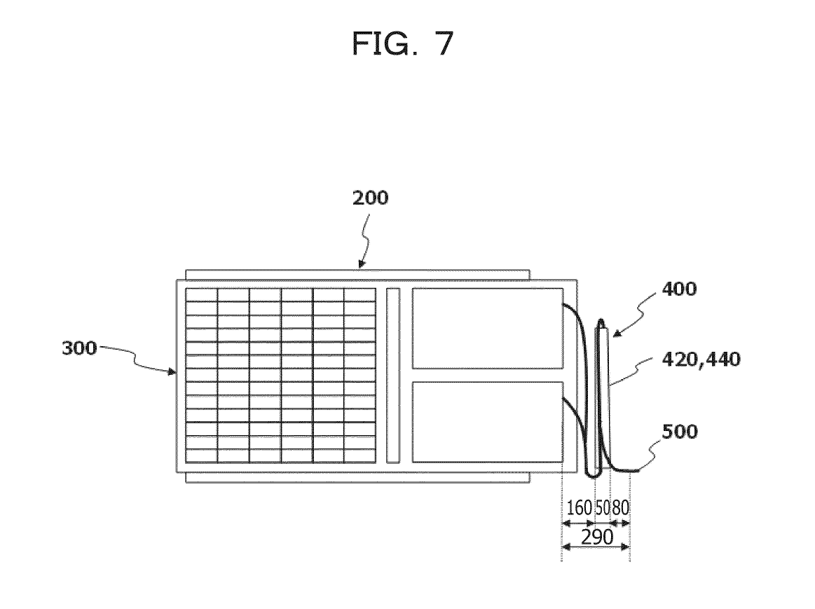

FIG. 7 illustrates an exemplary space occupied by a cable management arm. In the CMA 400, since the first arm member 420 and the second arm member 440 are positioned to be overlapped with each other on the cross section of the rack 200 as illustrated in FIG. 7, a depth space of about 50 mm which corresponds to the width of the first arm member 420 and the second arm member 440 exists at that location. Since the location where the cable 500 is guided from the storage device 300 to the CMA 400 is substantially the same as that of FIG. 6, a depth space of 160 mm (80×2=160 mm) exists. At the location where the cable 500 is pulled out from the CMA 400 to the outside, a depth space of 80 mm exists. Therefore, in the CMA 400 illustrated in FIG. 7, a depth space of 290 mm (160+50+80=290 mm) exists.

Since the depth space of the CMA 400 is reduced by an amount of about 190 mm from 480 mm to 290 mm, the depth size of the storage device 300 may be increased by that amount. When the storage device 300 is loaded with hard discs, for example, one raw of 3.5 inch hard discs, having a case size of about 150 mm long, about 100 mm wide, and about 20 mm high, may be further mounted.

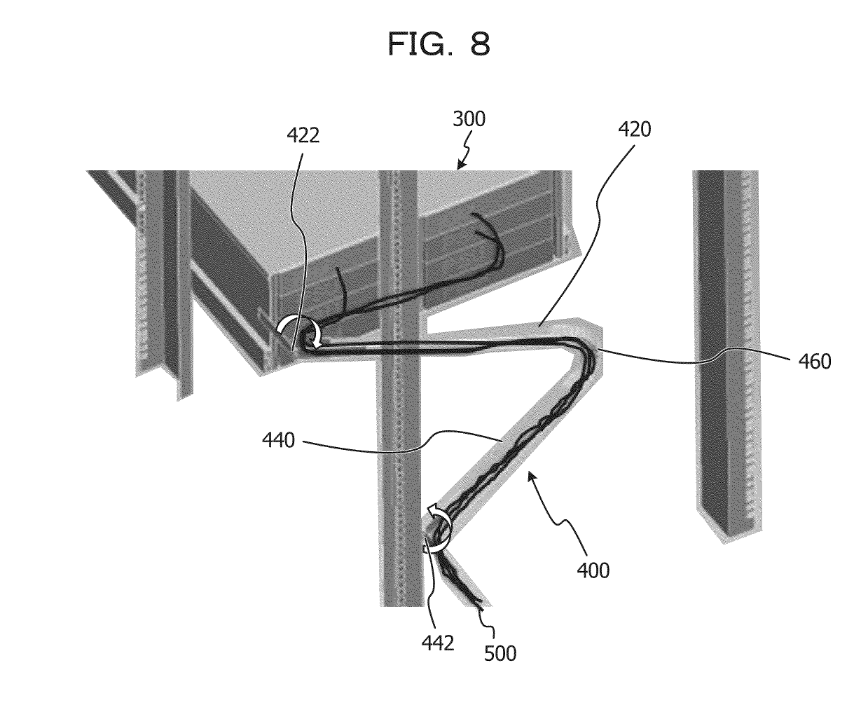

FIG. 8 illustrates an exemplary cable management arm. FIG. 8 is a perspective view illustrating a state of the cable management arm when a storage device is pulled out from the rack. When the storage device 300 is pulled out from the rack 200 as illustrated in FIG. 8, the first arm member 420 and the second arm member 440 of the CMA 400 are rotated around the first rotation shaft 422 and the second rotation shaft 442, respectively, so that the angle formed by both of them is gradually increased. Thus, the cable 500 supported by the CMA 400 is developed forward following the movement of the storage device 300 without interfering with, for example, the rack 200 or other storage devices 300. When the storage device 300 is pushed into the rack 200, the cable 500 undergoes a reverse process.

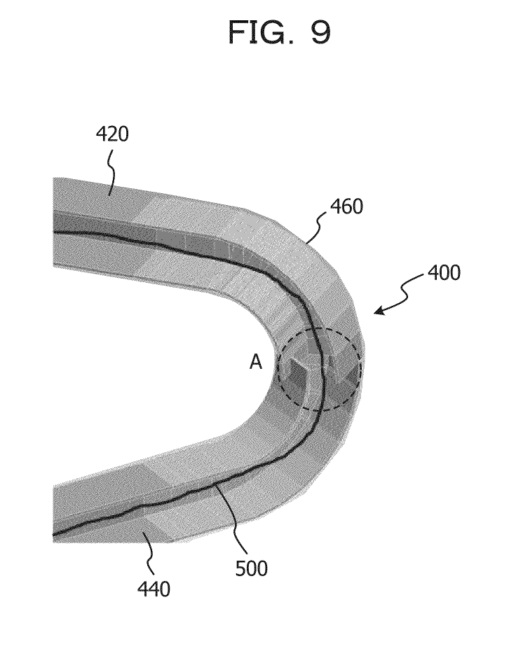

FIG. 9 illustrates an exemplary twist occurring in a cable supported on a cable management arm. For example, in the CMA 400, in a state where the storage device 300 is pulled out from the rack 200, a twist may occur in the “A” portion of the cable 500 which is supported by a connection member 460 that couples the first arm member 420 and the second arm member 440, as illustrated in FIG. 9. The twist of the cable 500 may occur in a bent portion of the cable 500.

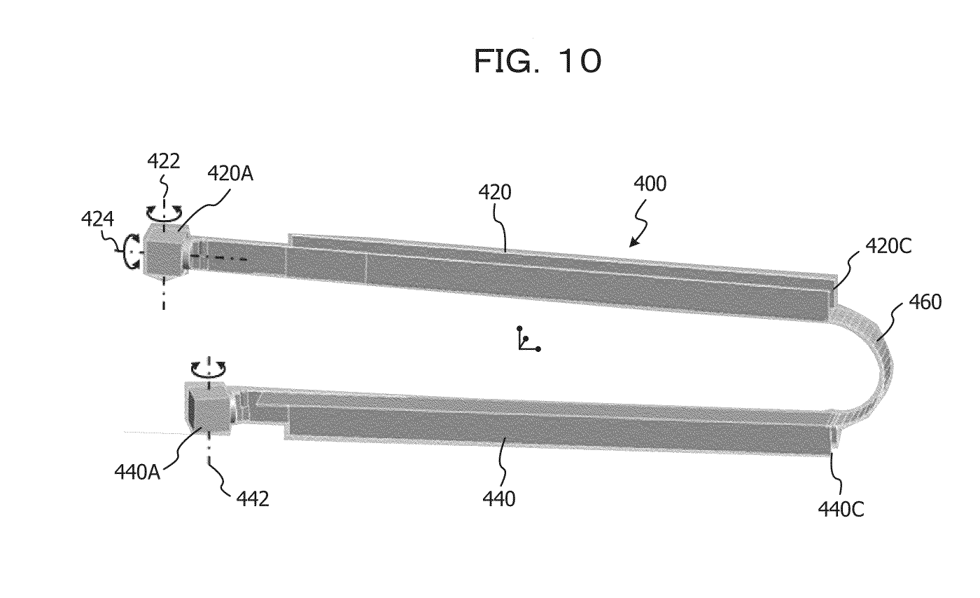

FIG. 10 illustrates an exemplary measure of reducing a twist of a cable. As illustrated in FIG. 10, the base end 420A of the first arm member 420 is fixed to the storage device 300 to be rotatable around a third rotation shaft 424 extending in the material axis direction of the first arm member 420 in addition to the first rotation shaft 422. According to this, when rotating around the first rotation shaft 422, the first arm member 420 is also rotated around the third rotation shaft 424 by a force applied to the cable 500. Therefore, the twist of the cable 500 is reduced and as a result, generated stress may be reduced.

A rotating mechanism 480 may automatically rotate the first arm member 420 around the first rotation shaft 422 and the third rotation shaft 424 using a force of pulling out the storage device 300 from the rack 200.

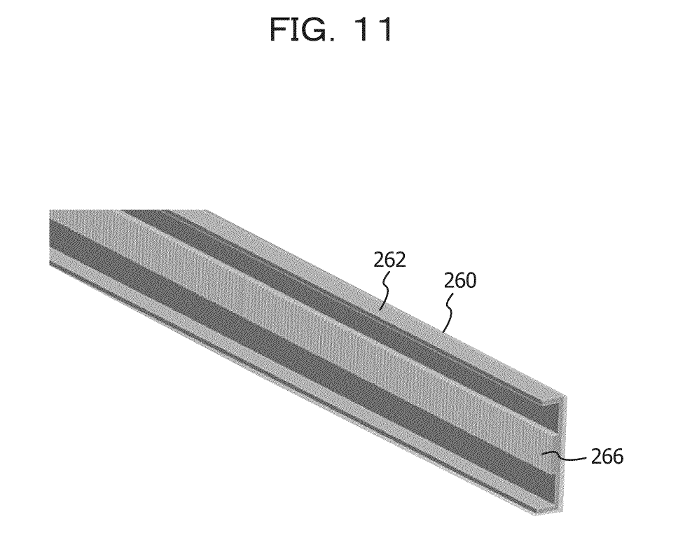

FIG. 11 illustrates an exemplary perspective view of a rotating mechanism. The rotating mechanism illustrated in FIG. 11 may be provided in a slide rail. On an inner surface of each of the outer rails 262 of the slide rails 260, for example, on each of the inner surfaces where a pair of left and right outer rails 262 face each other, a rack 266 with vertically extending teeth is formed as illustrated in FIG. 11. The rack 266 may be directly formed on the inner surface of each of the outer rails 262. The rack 266 may be formed as a separate member and secured to the inner surface of each of the outer rails 262.

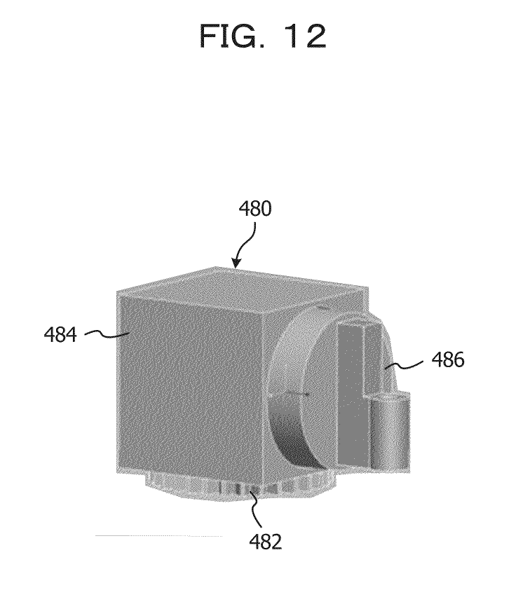

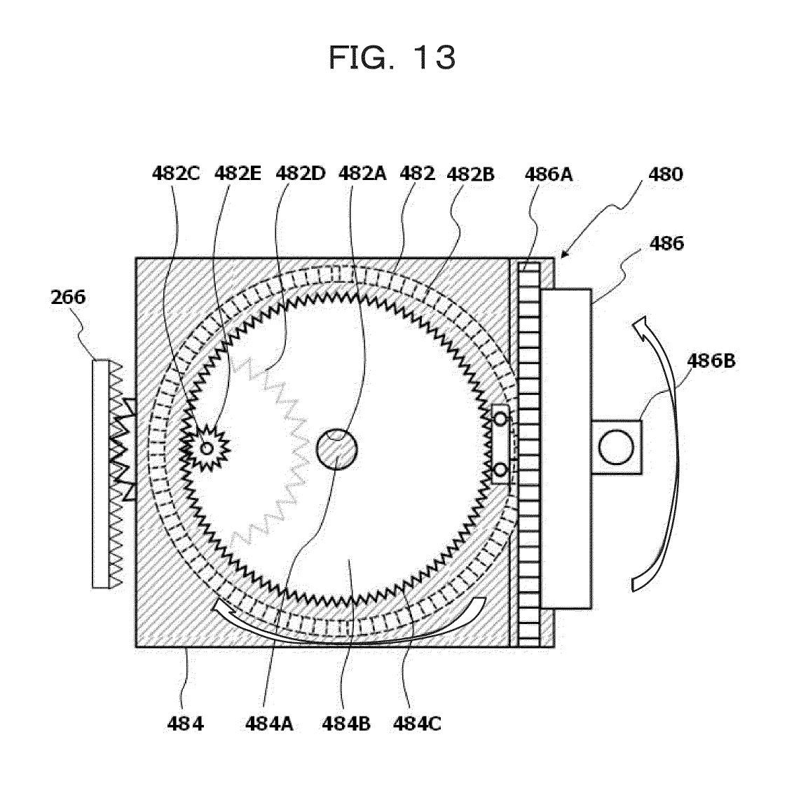

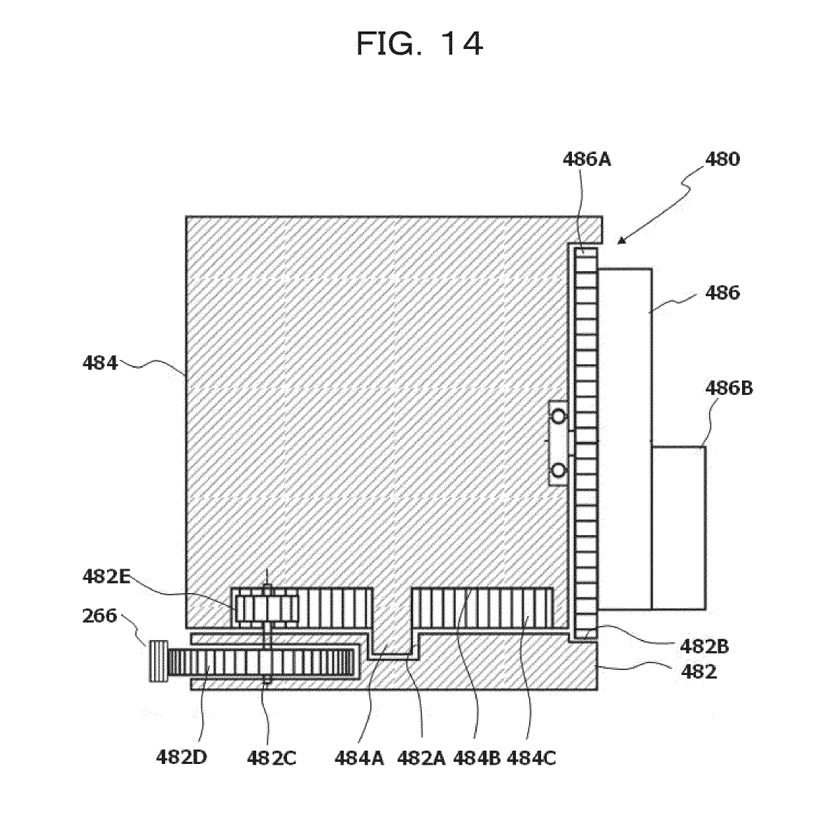

FIG. 12 illustrates an exemplary perspective view of a rotating mechanism. FIG. 13 illustrates an exemplary plan view of the rotating mechanism. FIG. 14 illustrates an exemplary side view of the rotating mechanism. The rotating mechanism illustrated in FIGS. 12 to 14 may rotate the first arm member. The base end 420A of the first arm member 420 is fixed to the rear surface of each storage device 300 through the rotating mechanism 480 as illustrated in FIGS. 12 to 14. Besides the rack 266, the rotating mechanism 480 includes a base member 482 integrally fixed to the storage device 300, a first rotating member 484 rotatably coupled to the base member 482, and a second rotating member 486 rotatably coupled to the first rotating member 484.

The base member 482 has a substantially circular shape when viewed in a plan view. A shaft hole 482A with a circular cross section is formed substantially at a center of the top surface of the base member 482. On a peripheral edge of the top surface of the base member 482, a toothed portion 482B is formed to extend substantially in an annular shape. A first gear 482D is mounted in the vicinity of the peripheral edge of the base member 482. The first gear 482D is engaged with the rack 266 of the slide rail 260 and is rotatable about a rotation shaft 482C extending in the vertical direction. The first gear 482D may be always engaged with the rack 266 of the slide rail 260. A second gear 482E is integrally fixed to an upper end of the rotation shaft 482C protruding upward from the top surface of the first gear 482D. The number of teeth of the second gear 482E is smaller than that of the first gear 482D.

The first rotating member 484 has a substantially regular hexahedron shape and is hollow or solid. A shaft portion 484A is formed to protrude substantially at a center of the bottom surface of the first rotating member 484 and rotatably fitted in a shaft hole 482A of the base member 482. In addition, a recess 484B, which is concentric to the shaft portion 484A and has a substantially circular cross section, is formed on the bottom surface of the first rotating member 484. Over the entire circumference of the peripheral surface of the recess 484B, an annular toothed portion 484C is formed to be engaged with the second gear 482E of the base member 482.

The second rotating member 486 has a substantially stepped columnar shape. The second rotating member 486 is connected rotatably to around a rotation shaft extending in the material axis direction of the first arm member 420 at a side surface of the first rotating member 484, for example, the side surface positioned opposite to the rack 266 of the slide rail 26. Over the entire circumference of a large diameter portion of the second rotating member 486, a toothed portion 486A is formed to be engaged with the toothed portion 482B of the base member 482. On an outer surface of a small diameter portion of the second rotating member 486, for example, on an outer surface spaced away from the toothed portion 486A, a fixing portion 486B is formed to fix the base end 420A of the first arm member 420. The fixing portion 486B integrates the base end 420A of the first arm member 420 and may have any shape.

When the storage device 300 is pulled out from the rack 200, the outer rail 262 of the slide rail 260 and the storage device 300 are relatively displaced. Thus, the first gear 482D engaged with the rack 266 of the outer rail 262 is rotated. When the first gear 482D is rotated, the second gear 482E integrated with the first gear 482D is rotated such that the position of the toothed portion 484C of the first rotating member 484 which is engaged with the first gear 482D is changed. Therefore, the first rotating member 484 is rotated about the shaft hole 482A of the base member 482 and rotates the first arm member 420 around the first rotation shaft 422. At this time, when the number of teeth of the first gear 482D, the second gear 482E, and the toothed portion 484C of the first rotating member 484 is properly set, the first rotating member 484 may be rotated up to 90 degrees as the storage device 300 is pulled out. For example, when the first rotating member 484 is rotated 90 degrees with respect to the base member 482, the first arm member 420 becomes substantially parallel to the depth direction of the rack 200 so that the sliding width of the storage device 300 with respect to the rack 200 may become the maximum.

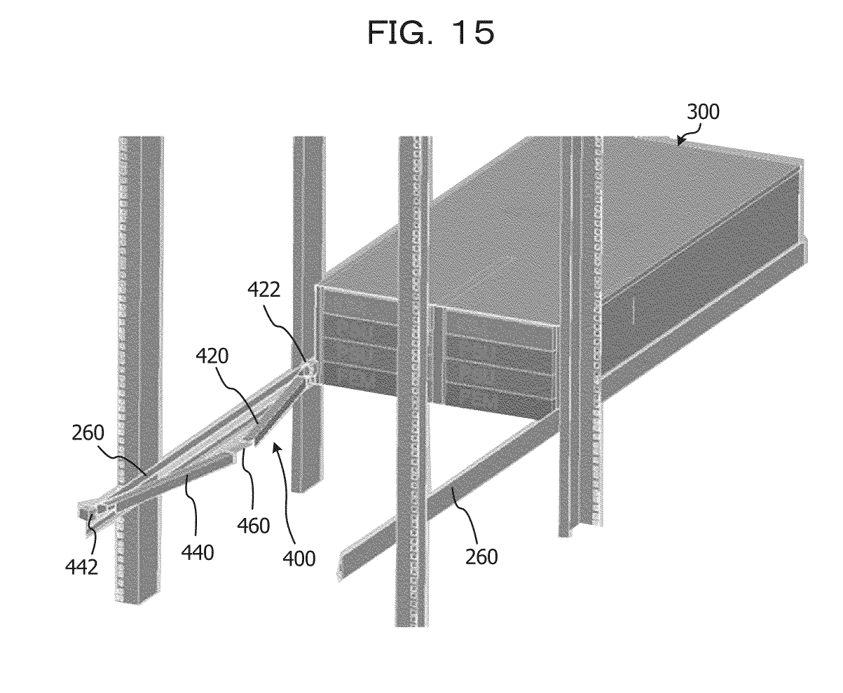

FIG. 15 is an exemplary perspective view illustrating a first arm member and a second arm member in a developed state. For example, when the first rotating member 484 is rotated with respect to the base member 482, the position of the toothed portion 486A of the second rotating member 486 which is engaged with the toothed portion 482B of the base member 482 is changed and the second rotating member 486 is rotated. When the second rotating member 486 is rotated, the first arm member 420 fixed to the fixing portion 486B is rotated around the third rotation shaft 424. At this time, when the number of teeth of the toothed portion 482B of the base member 482 and the toothed portion 486A of the second rotating member 486 is properly set, the second rotating member 486 may be rotated up to 180 degrees as the storage device 300 is pulled out. For example, when the second rotating member 486 is rotated 180 degrees with respect to the first rotating member 484, as illustrated in FIG. 15, the opening of the first arm member 420 rotates to a position where the opening faces the second arm member 440.

Using the force of pulling out the storage device 300 from the rack 200, the first arm member 420 may be rotated around the first rotation shaft 422 up to 90 degrees, and the first arm member 420 may be rotated around the third rotation shaft 424 up to 180 degrees. Therefore, the twist of the bent portions of the cable 500 supported on the CMA 400 may be reduced such that the produced torsional stress may be reduced. When the torsional stress of the cable 500 is reduced, a simple bending moment may be applied to the cable 500. Thus, for example, the life span may be increased by suppressing deterioration.

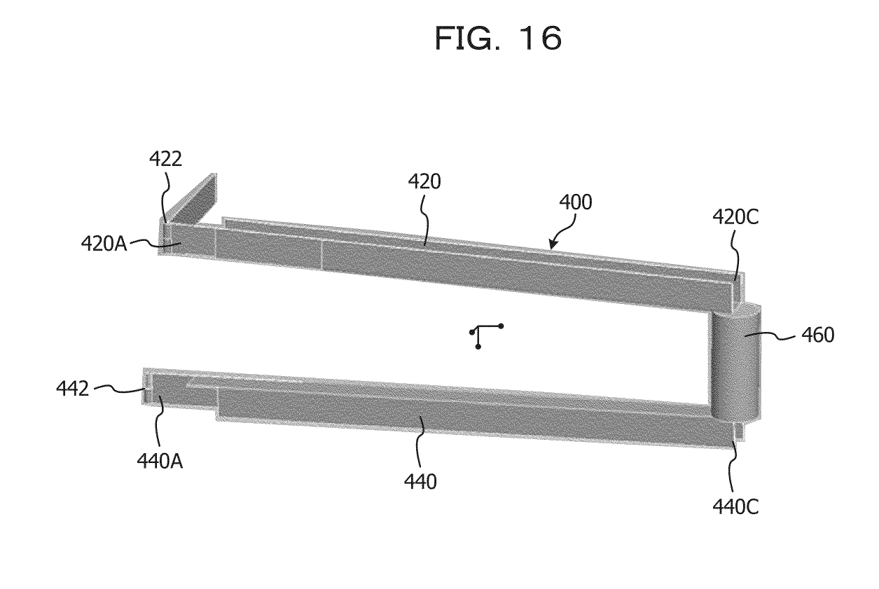

FIG. 16 illustrates an exemplary connection member. FIG. 16 is a perspective view illustrating a connection member that couples the first arm member and the second arm member with each other. In the CMA 400, a member which is rotatable around a rotation shaft extending in the vertical direction and has a substantially columnar shape as illustrated in FIG. 16 may be used as the connection member 460 that connects the front end 420C of the first arm member 420 and the front end 440C of the second arm member 440. All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device mounting apparatus comprising:
a rack configured to be slidably loaded with an electronic device; and
a cable management arm configured to support a cable of the electronic device,
wherein the cable management arm includes:
a first arm member including a first base end which is fixed to be rotatable with respect to the electronic device around a first rotation shaft extending in a vertical direction; and
a second arm member including a second base end which is fixed to be rotatable with respect to the rack around a second rotation shaft extending in the vertical direction.

2. The electronic device mounting apparatus according to claim 1, wherein the first arm member and the second arm member are installed to be spaced apart from each other by a distance in the vertical direction.

3. The electronic device mounting apparatus according to claim 1, wherein a first front end of the first arm member and a second front end of the second arm member are coupled with each other through a relatively displaceable connection member.

4. The electronic device mounting apparatus according to claim 1, wherein the first base end is rotatable around a third rotation shaft extending in a material axis direction of the first arm member.

5. The electronic device mounting apparatus according to claim 4, further comprising:
a rotating mechanism configured to rotate the first base end around each of the first rotation shaft and the third rotation shaft, using a force of pulling out or pushing into the electronic device with respect to the rack.

6. The electronic device mounting apparatus according to claim 5, wherein the rotating mechanism rotates the first base end 180 degrees around the third rotation shaft.

7. The electronic device mounting apparatus according to claim 5, wherein the rotating mechanism rotates the first base end 90 degrees around the first rotation shaft.

8. The electronic device mounting apparatus according to claim 2, wherein the distance is at least two times a tolerable minimum bending radius of the cable.

9. The electronic device mounting apparatus according to claim 1, wherein each of the first arm member and the second arm member includes a plurality of insertion holes through which a binding band is inserted.

10. The electronic device mounting apparatus according to claim 1, wherein the cable includes at least one of a power cable and a data cable.

11. The electronic device mounting apparatus according to claim 1, wherein the first arm member and the second arm member are coupled to one surface of the electronic device, and
the first arm member and the second arm member are disposed to be overlapped with each other when viewed from a surface direction of the one surface.

12. The electronic device mounting apparatus according to claim 1, wherein the first arm member and the second arm member are disposed in the vertical direction to be overlapped with each other when viewed from the vertical direction.
